(19) United States
(12) Patent Application Publication
(10) Pub. No.: US 2017/0311455 A1
(43) Pub. Date: Oct. 26, 2017

(54) Method for Producing a Multi-Layer Substrate and Multi-Layer Substrate

(71) Applicant: EPCOS AG, Muenchen (DE)

(72) Inventors: Sebastian Brunner, Graz (AT); Gerhard Fuchs, Steinerkirchen (AT); Annette Fischer, Lannach (AT)

(73) Assignee: EPCOS AG, Munchen (DE)

(21) Appl. No.: 15/315,359

(22) PCT Filed: Aug. 12, 2015
(86) PCT No.: PCT/EP2015/068572

§ 371 Date: Jun. 2, 2017

(30) Foreign Application Priority Data
Aug. 28, 2014 (DE) 10 2014 112 365.4

(51) Int. Cl. H05K 3/42; H05K 1/03; H05K 1/09; H05K 1/11

(52) U.S. Cl. CPC H05K 3/429; H05K 1/115; H05K 1/0306; H05K 1/09; H05K 2201/0195

(57) ABSTRACT

A method for producing a multilayer substrate (1) is specified, wherein a main body (26) comprising a plurality of ceramic layers (2) is provided, wherein at least one layer (2) comprises a hole (27). In order to form a plated-through hole (4, 18, 20, 21), the hole (27) is filled with a metal by depositing the metal from a solution. Furthermore, a multilayer substrate is specified wherein a plated-through hole (4, 18, 20, 21) in the interior of the main body (26) is connected to a further contact (11), wherein the plated-through hole (4, 18, 20, 21) comprises a different material than the further contact (11) and/or is produced by a different method.

macros hash =multilayer substrate star =plated-throuch hole pie =connection contact alpha =photoresist mask beta =further contact gamma =HTCC technology delta =main body matt =ceramic layer

A ceramic multilayer substrate is specified. By way of example, the multilayer substrate serves as a carrier for components, in particular for electrical components. By way of example, an LTCC (low temperature cofired ceramics) or an HTCC (high temperature cofired ceramics) ceramic composite is involved. The multilayer substrate comprises a plated-through hole (via), which is connected to a connection contact for example for contacting a component. The achievable packing density of the components is crucially dependent on the configuration of the vias and of the connection contacts.

The document DE 10 2004 030 800 A1 discloses a ceramic multilayer substrate wherein solderable connection pads are produced by depositing a metal onto the ceramic substrate.

It is an object of the present invention to specify an improved multilayer substrate and a method for producing a multilayer substrate.

In accordance with a first aspect of the present invention, a method for producing a multilayer substrate is specified. In this case, a main body comprising a plurality of ceramic layers is provided. At least one of the layers, in particular an outermost layer of the main body, comprises a hole. The hole is filled with a metal by depositing the metal from a solution. In this way, it is possible to produce a plated-through hole through at least one layer.

By way of example, the ceramic composite is produced using LTCC or HTCC technology. In this case, green sheets for forming the ceramic layers are provided and stacked one above another. An outermost layer of the layer stack is provided with a hole. The hole is introduced for example by means of a laser or by stamping. The layer stack is sintered. In order to produce the plated-through hole, the hole is filled by depositing a metal from a solution after sintering. Preferably, the hole is filled completely. The metal contains or is copper, for example.

By way of example, an electrolytic method is used for depositing the metal. In particular, an external current source is connected. In this case, the surface to be coated becomes the cathode on which the metal deposits from the solution.

That surface of the main body on which the metal is intended to be deposited, in particular the surface within the hole, is pretreated before the metal is deposited, for example. In particular, a seed layer can be applied to the surface, which facilitates the deposition of the metal or actually makes it possible in the first place. By way of example, as a seed layer a metalization is applied on the surface of the ceramic. Afterward, the metal is applied on the seed layer by deposition from a solution.

The production of a plated-through hole by depositing a metal has the advantage that it is possible to introduce the metal for the plated-through hole only after the sintering of the ceramic composite. Consequently, the choice of the metal is largely independent of the manner of production of the ceramic composite, e.g. independent of whether an LTCC or HTCC technology is used. By way of example, firing pastes containing tungsten or molybdenum are usually used for the plated-through holes in HTCC technology. When the plated-through hole is produced by depositing a metal, in HTCC technology as well it is possible instead to use copper, for example, as material for the plated-through hole.

In accordance with a further aspect of the invention, a multilayer substrate is specified, wherein the multilayer substrate comprises a main body having a plurality of ceramic layers. At least one of the layers comprises a plated-through hole, wherein the plated-through hole comprises a metal introduced by deposition from a solution. All properties disclosed with regard to the method and the multilayer substrate are also disclosed correspondingly with regard to the respective other aspects, and vice versa, even if the respective property is not mentioned explicitly in the context of the respective aspect.

In one embodiment, the hole and accordingly the plated-through hole formed by depositing the metal leads only through a portion of the ceramic layers. By way of example, the plated-through hole leads only through the outermost ceramic layer. In a further embodiment, the hole and accordingly the plated-through hole formed by deposition leads through a plurality of ceramic layers. The plated-through hole can also lead through the entire layer stack.

In one embodiment, the multilayer substrate comprises a further contact arranged in the interior of the main body and connected to the plated-through hole. In one embodiment, the further contact differs from the plated-through hole in terms of the material and/or the production method.

In one embodiment, the further contact comprises silver, molybdenum or tungsten. The plated-through hole comprises copper, for example. In one embodiment, the further contact comprises the same material as the plated-through hole. By way of example, both the further contact and the plated-through hole comprise copper or substantially consist of copper.

In one embodiment, a paste is used for producing the further contact, said paste being sintered jointly with the green sheets. The plated-through hole is produced by deposition of the metal for example only after sintering. The combination of the plated-through hole produced by deposition with a further contact composed of a fired paste has the advantage that even regions of the main body which cannot be reached or can only be reached poorly during a deposition method can be contacted by the further contact.

In one embodiment, the further contact comprises an inner ply arranged on a ceramic layer in the interior of the main body. By way of example, a passive component or an interconnection structure is realized by the inner ply. The inner ply is applied for example as paste on a green sheet, which is then arranged with the other green sheets to form a stack and sintered.

As an alternative or in addition thereto, the further contact can comprise a further plated-through hole leading through at least one further ceramic layer. By way of example, the further plated-through hole continues the plated-through hole formed by deposition into the interior of the main body.

In one embodiment, upon depositing the metal from the solution, a connection contact for connecting the component is also produced on the outer side of the main body. The connection contact is arranged above the plated-through hole for example as seen from a plan view of the outer side. The connection contact can be formed as a connection pad. The connection pad has for example a greater width than the plated-through hole.

The connection contact is preferably produced in the same method as the plated-through hole. The connection contact preferably comprises the same material as the plated-through hole. The connection contact can additionally be provided with a cover layer in order to form a planar, solderable and bondable surface. The cover layer can contain a metal, for example, which is deposited in an electroless fashion or with the connection of an external current source. By way of example, this involves nickel, palladium, gold, silver and/or tin.

In the case of such a plated-through hole applied by deposition and a connection contact applied thereon, it is possible to produce a particularly planar surface of the connection contact. This makes it possible, for example, to apply solder balls for fixing a component directly above the plated-through hole on the connection contact, such that the packing density of components can be increased.

In one embodiment, the connection contact is embodied in the form of a bump or a pillar. In this case, the connection contact projects from the main body. A component can be placed onto the connection contact at a distance from the surface of the main body. In particular, in the case of a bump- or pillar-like configuration of the connection contact, solder balls for fixing the component are not required. Such a configuration of the connection contact allows a further increase in the packing density of the components.

In accordance with a further aspect of the present invention, a multilayer substrate is specified, wherein the multilayer substrate comprises a main body having a plurality of ceramic layers. The multilayer substrate comprises a plated-through hole and a further contact connected thereto, wherein the plated-through hole leads through at least one of the layers, and the further contact is arranged in the interior of the main body. The further contact comprises a different material than the plated-through hole and/or is produced by a different production method than the plated-through hole.

By way of example, the further contact comprises silver and the plated-through hole comprises copper. By way of example, the further contact is formed by a fired paste. The plated-through hole is produced for example only after the sintering of the main body, in particular by the deposition of a metal from a solution.

In accordance with a further aspect of the present invention, a multilayer substrate is specified. The multilayer substrate comprises a main body having a plurality of ceramic layers, wherein the main body is produced using HTCC technology and comprises an electrical contact leading through at least one of the layers, wherein the plated-through hole contains copper. The plated-through hole is introduced for example by depositing a metal from a solution after the sintering of the main body.

Usually, in HTCC technology, use is made of tungsten or molybdenum as materials for a plated-through hole. A plated-through hole composed of copper enables, inter alia, a cost saving and also a better thermal and electrical conductivity.

A plurality of aspects of an invention are described in the present disclosure. All properties disclosed with respect to the method or one of the multilayer substrates are also correspondingly disclosed with regard to the respective other aspects, and vice versa, even if the respective property is not mentioned explicitly in the context of the respective aspect.

The subjects described here are explained in greater detail below on the basis of schematic exemplary embodiments that are not true to scale.

In the figures:

FIG. 1 shows one embodiment of a multilayer substrate in a cross-sectional view,

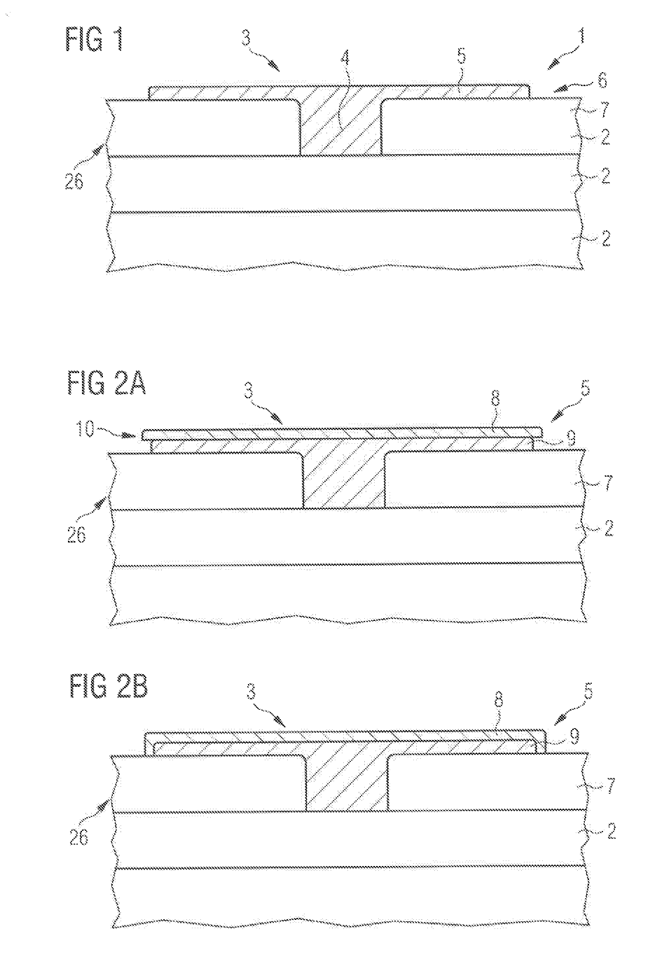

FIG. 2A shows a further embodiment of a multilayer substrate in a cross-sectional view,

FIG. 2B shows a further embodiment of a multilayer substrate in a cross-sectional view,

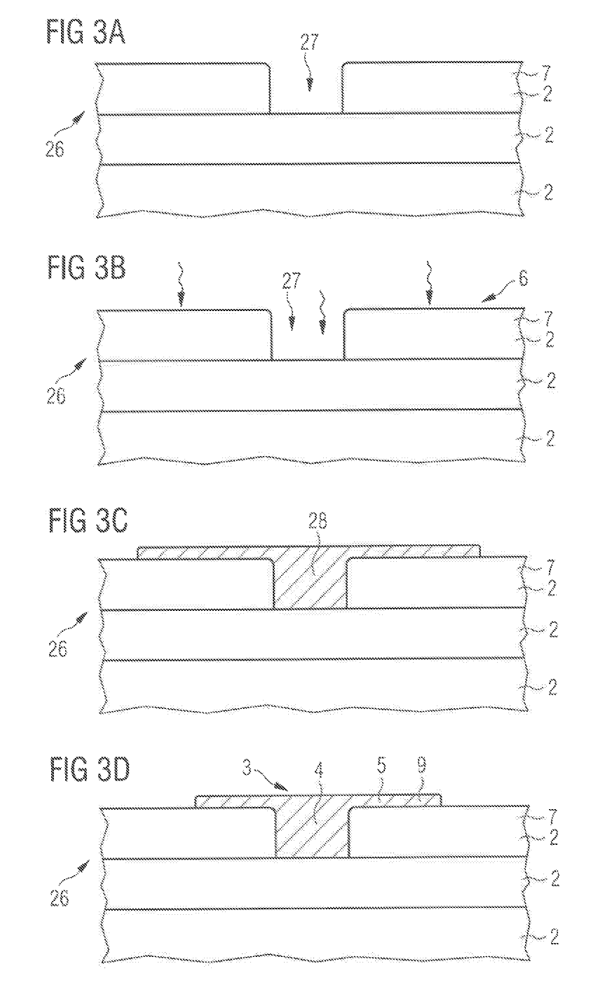

FIGS. 3A to 3D show method steps in a method for producing a multilayer substrate,

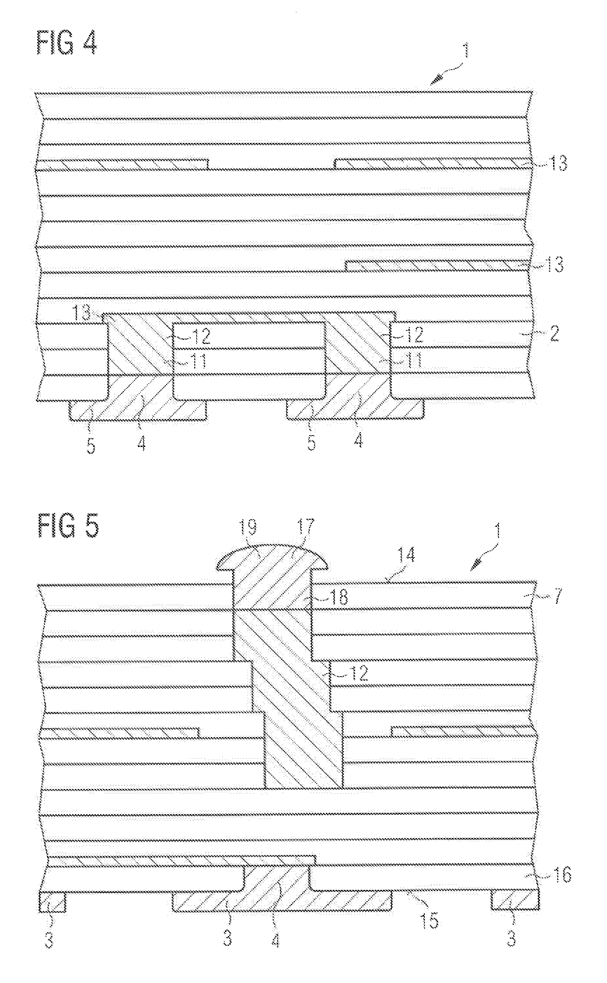

FIGS. 4 to 7 show further embodiments of multilayer substrates in cross-sectional views.

Preferably, in the following figures, identical reference signs refer to functionally or structurally corresponding parts of the different embodiments.

FIG. 1 shows in a cross-sectional view a multilayer substrate 1 having a main body 26 comprising a plurality of ceramic layers 2 arranged one above another. The multilayer substrate 1 comprises an electrical contact 3 comprising a plated-through hole 4 and a connection contact 5. The connection contact 5 is formed as a connection pad. The electrical contact 3 is designed in particular for contacting a component, for example a chip (not depicted), which is arranged on the multilayer substrate. By way of example, the component is an LED, a sensor, a SAW filter or a fluidic reactor. In particular, an electrical component can be involved. The multilayer substrate serves for example as a carrier for the component and/or as encapsulation, in particular in the form of a so-called package. By way of example, the component is connected to the connection contact 5 by a bonding wire. The component can also be connected to the connection contact 5 by solder balls.

However, the connection contact 5 can also serve as mechanical and/or electrical connection of a cover or of a further substrate, for example in order to form a package-on-package system. By way of example, the further component is soldered or adhesively bonded onto the connection contact 5.

The plated-through hole 4 leads from an outer side 6 of the multilayer substrate 1 through an outermost ceramic layer 7, for example the topmost layer of the layer stack. In particular, the plated-through hole 4 runs from the connection contact 5 into the interior of the substrate 1. The plated-through hole 4 is embodied as a so-called blind via, that is to say that it does not lead completely through the substrate. The connection contact 5 is arranged on the outer side 6 of the main body 26, in particular on an outermost layer 7. The connection contact 5 is formed integrally with the plated-through hole 4. In particular, the plated-through hole 4 and the connection contact 5 are formed from the same material and are produced in the same method. By way of example, the plated-through hole 4 and the connection contact 5 comprise copper and are produced by depositing a metal from a solution.

The plated-through hole 4 has for example a width of 80 μm. The connection contact 5 in the form of a connection pad is made significantly wider than the plated-through hole 4. By way of example, the connection pad has a width of 250 μm and a height of 20 μm.

FIGS. 2A and 2B show, in a cross-sectional view in each case, a multilayer substrate 1 wherein the connection contact 5 is additionally provided with a cover layer 8. The cover layer 8 is applied on a main layer 9 embodied like the connection contact 5 in FIG. 1. By virtue of the cover layer 8, the connection contact 5 obtains a particularly smooth, solderable and bondable surface. The cover layer 8 can also afford protection against corrosion.

The cover layer 8 can be embodied in a multilayered fashion. By way of example, the cover layer 8 comprises a nickel layer and a silver layer, wherein the nickel layer functions as a soldering barrier. Alternatively, the cover layer 8 comprises for example a nickel layer and a gold layer. A palladium layer can additionally be applied on the nickel layer. Consequently, the cover layer 8 is constructed in a multilayered fashion for example with Ni—Au or Ni—Pd—Au.

In the case of the embodiment in accordance with FIG. 2A, the cover layer 8 covers only the top side of the main layer 9. The connection contact 5 comprises an open edge 10. In this case, the main layer 9 is structured for example only after the cover layer 8 has been applied, as will be explained below with regard to FIGS. 3A to 3D.

In the case of the embodiment in accordance with FIG. 2B, the cover layer 8 also covers the lateral regions of the main layer 9, such that the main layer 9 is completely covered by the cover layer 8. In this case, the main layer 9 is for example already structured before the cover layer 8 is applied, as will be explained below with regard to FIGS. 3A to 3D.

FIGS. 3A to 3D show method steps for producing such a multilayer substrate.

FIG. 3A shows a main body 26 for a multilayer substrate. In order to produce the main body 26, green sheets for forming ceramic layers 2 are arranged one above another to form a layer stack and are sintered jointly. For the plated-through hole 4, the green sheet that later forms the outermost ceramic layer 7 is provided with a hole 27. By way of example, the hole is introduced by stamping or by means of a laser.

The green sheets contain for example a ceramic powder, a binder and a glass proportion as a sintering aid. By way of example, aluminum oxide is used as ceramic powder. In one embodiment, LTCC (low temperature cofired ceramics) technology is employed. In this case, sintering is performed for example at a temperature of around 900° C. Alternatively, HTCC (high temperature cofired ceramics) technology is employed. In this case, sintering is performed at a very high temperature, for example in the region of 1600° C. Here the green sheets contain no glass proportion, for example.

After the sintering of the layer stack, the surface of the ceramic is pretreated, such that a deposition of a metal for forming the electrical contact is facilitated or made possible in the first place.

FIG. 3B schematically shows the step for the pretreatment of the surface. In particular, a seed layer is produced within the hole 27 and on the outer side of the main body 26. The seed layer is for example 100 nm-500 nm thick.

In one embodiment, the surface within the hole 27 and on the outer side 6 of the main body 26 is activated chemically. During the activation, the surface is treated for example with a palladium-containing solution, for example a palladium chloride solution. In this case, palladium atoms deposit on the surface and catalyze the further metalization. As an alternative thereto, the seed layer can also be applied by sputtering or by means of a PVD method (Physical Vapor Deposition). The seed layer comprises titanium, copper and/or chromium, for example.

Afterward, a metalization 28 is produced on the activated area by depositing a metal from a solution.

FIG. 3C shows the multilayer substrate 1 wherein a metalization 28 is deposited in the hole 27 and on the outer side 6. The hole 27 is filled completely with the metal. By way of example, copper is deposited. This can be carried out in two stages, wherein a relatively thin copper layer is firstly deposited in an electroless fashion and then reinforced electrolytically.

The metalization 28 is subsequently structured in order to form the connection contact 5. For this purpose, by way of example, a photoresist mask is applied on the metalization 28 on the outer side 6 of the layer stack, is exposed in accordance with a desired pattern and is developed. The regions not provided for the connection contact 5 are then not covered by the photoresist mask. The regions not covered are subsequently etched. By way of example, an aqueous solution containing iron(III) ions is used as an etchant. The photoresist mask is subsequently removed, for example using a solvent.

FIG. 3D shows the multilayer substrate with the now structured connection contact 5 and the plated-through hole 4.

During production by the method described, the plated-through hole 4 and the connection contact 5 do not comprise a sintered metal paste. This enables an increase in the packing density of the components. In particular, the connection contact 5 can be structured with a better resolution in the case of the method described in comparison with what is possible in the case of printing with a paste by means of screen printing. A plurality of connection contacts 5, for example with an interspace of 30 μm, can be produced as a result. Furthermore, it is possible to produce a connection contact 5 with a particularly planar surface, such that e.g. solder balls can be arranged directly above the plated-through hole 4. This likewise enables an increase in the packing density. Moreover, such a contact 3 ensures a very good electrical, thermal, mechanical and radiofrequency linking of the external contact 5 to the interior of the substrate 1. Furthermore, the number of work steps can be reduced if the plated-through hole 4 and the connection contact 5 are produced in a common method.

Furthermore, the outermost layers 7, 16 of the main body 26 can be made very thin since said layers 7, 16 in the green state need no longer have a mechanical stability that is required for applying or introducing a paste.

In one embodiment, a further contact comprising a sintered paste adjoins the plated-through hole 4 in the interior of the substrate. In this case, a paste is applied on a green sheet or within a hole in a green sheet, said paste then being fired with the layer stack. In particular, a thick-film paste is involved.

In accordance with one variant for producing the connection contact 5, after the activation firstly, as described above, a metalization 28 is produced. A photoresist layer is applied on the metalization 28, is exposed and is developed, wherein the regions provided for the connection contact 5 remain free. In these regions that are not covered, a cover layer 8 (see FIG. 2A) is then applied on the metalization 28 with the connection of a current source or by means of an electroless method.

Afterward, the photoresist mask is removed and an etching step is carried out until the metalization 28 at the regions previously covered by the photoresist mask is removed down to the substrate. After the etching of the photoresist mask, by way of example, an open sandwichlike Cu—Ni—Ag edge 10 is obtained, as can be seen in FIG. 2A.

In accordance with an alternative variant, the cover layer is not applied until after the structuring of the basic metalization. By way of example, the cover layer is deposited on the main layer 9 in an electroless fashion in a chemical method. In this case, the cover layer 8 also covers the lateral regions of the main layer 9, as can be seen in FIG. 2B.

In accordance with an alternative variant, the structuring of the basic metalization can also be carried out in an additive method instead of in the subtractive method described above. For this purpose, by way of example, a photoresist mask is applied after the activation of the surface. The photoresist mask is exposed at the locations provided for the connection contact. The resist layer is removed at the exposed locations, such that at least one cutout is formed. The metalization for the connection contact is introduced electrolytically into the cutout. The remaining regions of the photoresist mask are subsequently removed.

FIG. 4 shows a multilayer substrate 1 comprising two plated-through holes 4 and connection contacts 5 produced by deposition. The two plated-through holes 4 have for example a distance of 400 μm to 500 μm. However, it is also possible to produce smaller distances, for example in the region of 100 μm.

The plated-through holes 4 are in each case connected to a further contact 11 in the interior of the substrate 1. The further contacts 11 in each case comprise a further plated-through hole 12 that continues the plated-through hole 4 produced by deposition into the interior of the substrate 1. The further plated-through hole 12 leads through two further ceramic layers 2.

The further plated-through hole 12 is formed from a fired paste. For this purpose, holes are introduced into the green sheets for the ceramic layers 2 which are intended to be provided with the further plated-through hole 12 and said holes are filled with a paste. The paste is sintered jointly with the green sheets. By way of example, the further plated-through hole 12 comprises silver. The plated-through hole 12 can also comprise copper. Particularly when an HTCC technology is used, suitable materials are also tungsten or molybdenum.

In addition, a plurality of metallic inner plies 13 are provided between ceramic layers 2, wherein one of the inner plies 13 is electrically connected to the further plated-through holes 12. By way of example, passive components and interconnection structures are realized by the inner plies 13. The inner plies 13 are also formed by a fired paste. For this purpose, the green sheets are printed with the paste, laminated and sintered.

FIG. 5 shows a further embodiment of a multilayer substrate 1. Here electrical contacts 3, 17 produced by deposition are provided both on an underside 15 and on a top side 14. The contacts 3, 17 respectively comprise plated-through holes 4, 18. The plated-through holes 4, 18 lead respectively only through the outermost layer 7, 16 of the substrate 1.

The contact 3 on the underside 15 comprises a plated-through hole 4 which is produced by deposition and which is directly connected to an inner ply 13. The inner ply 13 is formed by a fired paste.

The contact 17 on the top side 14 comprises a plated-through hole 18 which is produced by deposition and which is connected to a further plated-through hole 12. The further plated-through hole 12 is formed by a fired paste and leads through a plurality of ceramic layers 2 into the interior of the substrate 1.

The contact 17 on the top side 14 comprises a connection contact 19 in the form of a bump. The connection contact 19 is designed like the connection pad shown in the previous figures for the contacting of a component.

The bump is formed integrally with the plated-through hole 18 and is produced by deposition of a metal from a solution. By way of a example, a Cu bump is involved. The connection contact 19 can be provided with a coating, for example a tin coating, as a result of which Cu—Sn diffusion bonding is made possible. However, Cu—Cu bonding is also possible.

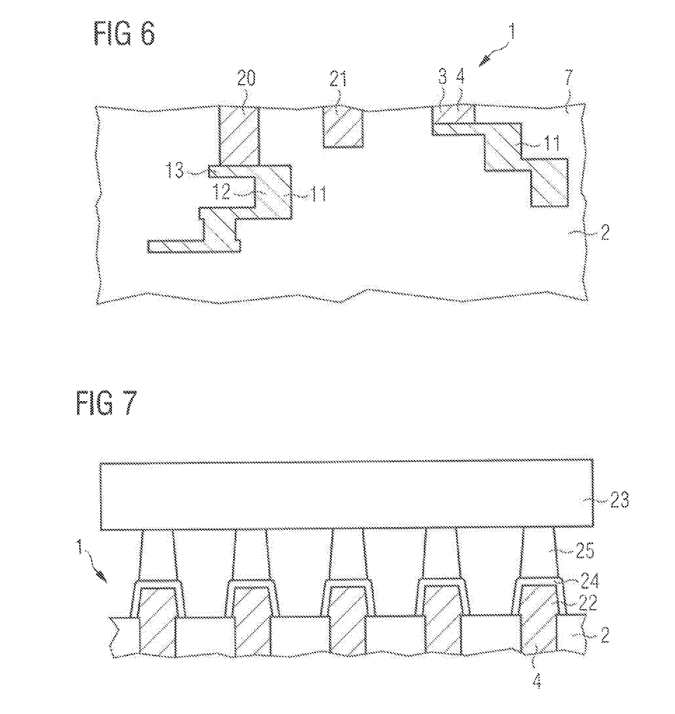

FIG. 6 shows a further embodiment for a multilayer substrate 1. The individual ceramic layers are not depicted, for reasons of clarity. A plurality of plated-through holes 4, 20, 21 produced by deposition are formed. One plated-through hole 4 leads only through the outermost layer 7 and is connected to a further contact 11 formed by a fired paste.

Two plated-through holes 20, 21 lead through a plurality of layers 2 of the substrate. One plated-through hole 21 is not connected to a further contact. The other plated-through hole 20 is connected to a further contact 11 comprising an inner ply 13 and a further plated-through hole 12. The inner ply 13 and the further plated-through hole 12 are formed by fired pastes.

In a further embodiment, a plated-through hole produced by deposition leads completely through the multilayer substrate.

FIG. 7 shows a further embodiment of a multilayer substrate 1 wherein the connection contacts 22 are of pillar-shaped design. So-called pillars are involved, which are used particularly in the case of power amplifiers. A component 23 is fixed on the multilayer substrate 1.

The connection contacts 22 are produced by deposition of a metal from a solution and are connected to plated-through holes 4. By way of example, the connection contacts 22 can be produced jointly with the plated-through holes 4. A solder layer 24 for fixing a component 23, in particular a tin layer, is applied on the connection contacts 22.

Alternatively, Cu—Cu bonding can also be used. The component 23 likewise comprises pillar-shaped connection contacts 25 that are placed onto the connection contacts 22 of the substrate 1 and are connected to them by the solder layer 24.

### LIST OF REFERENCE SIGNS

1 Multilayer substrate
2 Ceramic layer
3 Electrical contact
4 Plated-through hole
5 Connection contact
6 Outer side
7 Outermost layer
8 Cover layer
9 Main layer
10 Edge
11 Further contact
12 Further plated-through hole
13 Inner ply
14 Top side
15 Underside
16 Outermost layer
17 Electrical contact
18 Plated-through hole
19 Connection contact
20 Plated-through hole
21 Plated-through hole
22 Connection contact
23 Component
24 Solder layer
25 Connection contact of the component
26 Main body
27 Hole
28 Metalization

1. A method for producing a multilayer substrate,
A) Providing a main body (26) comprising a plurality of ceramic layers (2), wherein at least one layer (2) comprises a hole (27),
B) Filling the hole (27) with a metal by depositing the metal from a solution in order to form a plated-through hole (4, 18, 20, 21).

2. The method as claimed in claim 1, wherein the metal contains copper.

3. The method as claimed in either of claims 1 and 2, wherein the hole (27) leads through a plurality of ceramic layers (2).

4. The method as claimed in any of claims 1 to 3,
wherein the multilayer substrate (1) comprises in the interior of the main body (26) a further contact (11) connected to the plated-through hole (4, 18, 20, 21), wherein the further contact (11) differs from the plated-through hole (4, 18, 20, 21) in terms of the material and/or the production method.

5. The method as claimed in claim 4,
wherein the further contact (11) comprises silver, tungsten, molybdenum and/or copper.

6. The method as claimed in either of claims 4 and 5,
wherein the further contact (11) comprises a fired paste.

7. The method as claimed in any of claims 4 to 6,
wherein the further contact (11) comprises an inner ply (13) arranged on a ceramic layer (2) in the interior of the main body (26).

8. The method as claimed in any of claims 4 to 7,
wherein the further contact (11) comprises a further plated-through hole (12) leading through at least one further ceramic layer (2).

9. The method as claimed in any of claims 1 to 8,
wherein, upon depositing the metal, a connection contact (5, 19, 22) for connecting a component (23) is produced on an outer side (6, 14, 15) of the main body.

10. A multilayer substrate, comprising a main body (26) having a plurality of ceramic layers (2), wherein at least one of the layers (2) comprises a plated-through hole (4, 18, 20, 21) containing a metal introduced by deposition from a solution.

11. A multilayer substrate, comprising a main body (26) having a plurality of ceramic layers (2), wherein the multilayer substrate comprises a plated-through hole (4, 18, 20, 21) and a further contact (11) connected thereto, wherein the plated-through hole (4, 18, 20, 21) leads through at least one of the layers (2), and the further contact (11) is arranged in the interior of the main body (26), and wherein the plated-through hole (4, 18, 20, 21) comprises a different material than the further contact (11) and/or is produced by a different production method.

12. The multilayer substrate as claimed in claim 11,
wherein the plated-through hole (4, 18, 20, 21) comprises copper and the further contact comprises silver, tungsten, molybdenum and/or copper.

13. A multilayer substrate, comprising a main body (26) having a plurality of ceramic layers (2), wherein the main body (26) is produced using HTCC technology and comprises a plated-through hole (4, 18, 20, 21) leading through at least one of the layers, wherein the plated-through hole (4, 18, 20, 21) contains copper.

14. The multilayer substrate as claimed in any of claims 11 to 13,
wherein the further contact (11) comprises a further plated-through hole (18) in at least one ceramic layer.

15. The multilayer substrate as claimed in any of claims 11 to 14,
wherein the further contact (11) comprises an inner ply (13) in the interior of the main body (26), said inner ply being arranged on a ceramic layer (2).
